(19) United States
(12) Patent Application Publication
(10) Pub. No.: US 2024/0234297 A1
(43) Pub. Date: Jul. 11, 2024

(54) VIA STRUCTURE WITHOUT LINER INTERFACE

(71) Applicant: International Business Machines Corporation, Armonk, NY (US)

(72) Inventors: Brent A. Anderson, Jericho, VT (US); Nicholas Anthony Lanzillo, Wynantskill, NY (US); Lawrence A. Clevenger, Saratoga Springs, NY (US); Ruilong Xie, Niskayuna, NY (US); Christopher J. Penny, Saratoga Springs, NY (US); Kisik Choi, Watervilet, NY (US); John Christopher Amold, North Chatham, NY (US)

(21) Appl. No.: 18/093,713

(22) Filed: Jan. 5, 2023

(51) Int. Cl. H01L 23/522; H01L 21/768; H01L 23/532

(52) U.S. Cl. CPC H01L 23/5226; H01L 21/76807; H01L 21/76843; H01L 21/76879; H01L 23/53266

(57) ABSTRACT

An interconnect structure includes a first metal via disposed on a first metal line of a first metallization layer disposed in a dielectric layer, a first liner layer disposed on the dielectric layer, and a second metallization layer containing a first metal line disposed on the first liner layer and the first metal via.

### BACKGROUND

Generally, semiconductor devices can include a plurality of circuits which form an integrated circuit fabricated on a substrate. A complex network of signal paths can be routed to connect the circuit elements distributed on the surface of the substrate. Efficient routing of these signals can include the formation of multilevel or multilayered schemes (e.g., single or dual damascene wiring structures) during the back-end-of-line (BEOL) phase of manufacturing. Within an interconnect structure, conductive vias can run perpendicular to the substrate and conductive lines can run parallel to the substrate.

### SUMMARY

Illustrative embodiments of the present application include techniques for use in semiconductor manufacture. In an illustrative embodiment, an interconnect structure comprises a first metal via disposed on a first metal line of a first metallization layer disposed in a dielectric layer, a first liner layer disposed on the dielectric layer, and a second metallization layer comprising a first metal line disposed on the first liner layer and the first metal via.

According to another exemplary embodiment, an interconnect structure comprises a first metal via disposed on a first metal line of a first metallization layer disposed in a dielectric layer, a first liner layer disposed on the dielectric layer, and a second metallization layer comprising a first metal line disposed on the first liner layer and the first metal via. A top portion of the first metal via has a first width and a bottom portion of the first metal via has a second width different than the first width.

According to yet another exemplary embodiment, an interconnect structure comprises a first metallization layer comprising a metal line disposed in a first dielectric layer. The interconnect structure further comprises a metal via disposed on the metal line of a first metallization layer in the first dielectric layer. The interconnect structure further comprises a liner layer disposed on a portion of the first dielectric layer. The interconnect structure further comprises a second dielectric layer disposed on the liner layer and having a trench. The interconnect structure further comprises a barrier layer disposed on exterior surfaces of the first dielectric layer, the liner layer and the second dielectric layer. The interconnect structure further comprises a metal liner layer disposed on the barrier layer and the metal via. The interconnect structure further comprises a conductive metal disposed on the metal liner layer.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1 is a side cross-sectional view of a semiconductor structure for use at a first-intermediate fabrication stage, according to an illustrative embodiment.

FIG. 2 is a side cross-sectional view of the semiconductor structure for use at a second-intermediate fabrication stage, according to an illustrative embodiment.

FIG. 3 is a side cross-sectional view of the semiconductor structure for use at a third-intermediate fabrication stage, according to an illustrative embodiment.

FIG. 4 is a side cross-sectional view of the semiconductor structure taken for use at a fourth-intermediate fabrication stage, according to an illustrative embodiment.

FIG. 5 is a side cross-sectional view of the semiconductor structure for use at a fifth-intermediate fabrication stage, according to an illustrative embodiment.

FIG. 6 is a side cross-sectional view of the semiconductor structure for use at a sixth-intermediate fabrication stage, according to an illustrative embodiment.

FIG. 7 is a side cross-sectional view of the semiconductor structure, according to an alternative illustrative embodiment.

FIG. 8 is a side cross-sectional view of a semiconductor structure starting from FIG. 1 for use at a first-intermediate fabrication stage, according to an alternative illustrative embodiment.

FIG. 9 is a side cross-sectional view of the semiconductor structure for use at a second-intermediate fabrication stage, according to an alternative illustrative embodiment.

FIG. 10 is a side cross-sectional view of the semiconductor structure for use at a third-intermediate fabrication stage, according to an alternative illustrative embodiment.

FIG. 11 is a side cross-sectional view of the semiconductor structure taken for use at a fourth-intermediate fabrication stage, according to an alternative illustrative embodiment.

FIG. 12 is a side cross-sectional view of a semiconductor structure starting from FIG. 1 for use at a first-intermediate fabrication stage, according to another alternative illustrative embodiment.

FIG. 13 is a side cross-sectional view of the semiconductor structure for use at a second-intermediate fabrication stage, according to another alternative illustrative embodiment.

FIG. 14 is a side cross-sectional view of the semiconductor structure for use at a third-intermediate fabrication stage, according to another alternative illustrative embodiment.

FIG. 15 is a side cross-sectional view of the semiconductor structure taken for use at a fourth-intermediate fabrication stage, according to another alternative illustrative embodiment.

FIG. 16 is a side cross-sectional view of a semiconductor structure starting from FIG. 1 for use at a first-intermediate fabrication stage, according to another alternative illustrative embodiment.

FIG. 17 is a side cross-sectional view of the semiconductor structure for use at a second-intermediate fabrication stage, according to another alternative illustrative embodiment.

FIG. 18 is a side cross-sectional view of the semiconductor structure for use at a third-intermediate fabrication stage, according to another alternative illustrative embodiment.

FIG. 19 is a side cross-sectional view of the semiconductor structure taken for use at a fourth-intermediate fabrication stage, according to another alternative illustrative embodiment.

FIG. 20 is a side cross-sectional view of the semiconductor structure taken for use at a fifth-intermediate fabrication stage, according to another alternative illustrative embodiment.

FIG. 21 is a side cross-sectional view of a semiconductor structure for use at a first-intermediate fabrication stage, according to another alternative illustrative embodiment.

FIG. 22 is a side cross-sectional view of the semiconductor structure for use at a second-intermediate fabrication stage, according to another alternative illustrative embodiment.

FIG. 23 is a side cross-sectional view of the semiconductor structure for use at a third-intermediate fabrication stage, according to another alternative illustrative embodiment.

FIG. 24 is a side cross-sectional view of the semiconductor structure taken for use at a fourth-intermediate fabrication stage, according to another alternative illustrative embodiment.

FIG. 25 is a side cross-sectional view of the semiconductor structure taken for use at a fifth-intermediate fabrication stage, according to another alternative illustrative embodiment.

FIG. 26 is a side cross-sectional view of the semiconductor structure taken for use at a sixth-intermediate fabrication stage, according to another alternative illustrative embodiment.

FIG. 27 is a side cross-sectional view of a semiconductor structure starting from FIG. 21 for use at a first-intermediate fabrication stage, according to another alternative illustrative embodiment.

FIG. 28 is a side cross-sectional view of the semiconductor structure for use at a second-intermediate fabrication stage, according to another alternative illustrative embodiment.

FIG. 29 is a side cross-sectional view of the semiconductor structure for use at a third-intermediate fabrication stage, according to another alternative illustrative embodiment.

FIG. 30 is a side cross-sectional view of the semiconductor structure taken for use at a fourth-intermediate fabrication stage, according to another alternative illustrative embodiment.

FIG. 31 is a side cross-sectional view of the semiconductor structure taken for use at a fifth-intermediate fabrication stage, according to another alternative illustrative embodiment.

FIG. 32 is a side cross-sectional view of the semiconductor structure taken for use at a sixth-intermediate fabrication stage, according to another alternative illustrative embodiment.

FIG. 33 is a side cross-sectional view of the semiconductor structure taken for use at a sixth-intermediate fabrication stage, according to another alternative illustrative embodiment.

### DETAILED DESCRIPTION

This disclosure relates generally to semiconductor devices, and more particularly to interconnects having a via structure between metallization layers with no liner at the interface and methods for their fabrication. However, it is to be understood that embodiments of the invention are not limited to the illustrative methods, apparatus, systems and devices but instead are more broadly applicable to other suitable methods, apparatus, systems and devices.

A semiconductor device can include multiple metallization layers (“levels”), each including a conductive line (“line”) formed in a dielectric layer such as an interlevel dielectric layer (ILD). Although the term metallization is used herein, metallization layers can be formed to include any suitable conductive material in accordance with the embodiments described herein. Upper lines can be connected to lower lines by vias. Levels can be identified herein using the designation X, where X is a positive integer from 1 to N. The levels are identified from the level closest to the substrate to the level furthest from the substrate as 1 through N where 1 is the first or lowermost level and N is the last or uppermost level. A line in the X level is designated as an Mx line, and a via in the X level is designated as a Vx via. Note that there are no V₀ vias or via bars. When a line in an upper level is designated Mx, then a line in an immediately lower level can be designated M_{(X-1)}. Likewise, when a line in a lower level is designated Mx, then a line in an immediately higher level is designated M_{(X+1)}. For a first level (X=1), the line is M₁ and there are no “V₀” vias as the connection from M₁ to devices below M₁ is generally made through separately formed contacts in a contact layer (“CA”). For a second level (X=2), the line is M₂ and the vias are V₁ and, for a third level (X=3), the line is M₃ and the vias or via bars are V₃.

It is to be understood that the various layers, structures, and/or regions shown in the accompanying drawings are schematic illustrations that are not necessarily drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures.

Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be used to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the drawings to denote the same or similar features, elements, layers, regions, or structures, and thus, a detailed explanation of the same or similar features, elements, layers, regions, or structures will not be repeated for each of the drawings. Also, in the figures, the illustrated scale of one layer, structure, and/or region relative to another layer, structure, and/or region is not necessarily intended to represent actual scale.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 10% or less than the stated amount or 1% or less.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

Presently, interconnects are fabricated with a liner layer formed at the interface between a metal via and a metal line of a second metallization layer. This, however, can lead to an increased via resistance. The illustrative embodiments described herein overcome the foregoing drawbacks by utilizing a subtractive patterning process to remove a liner layer from an interface of the metal via and metal line of the second metallization layer thereby reducing the via resistance.

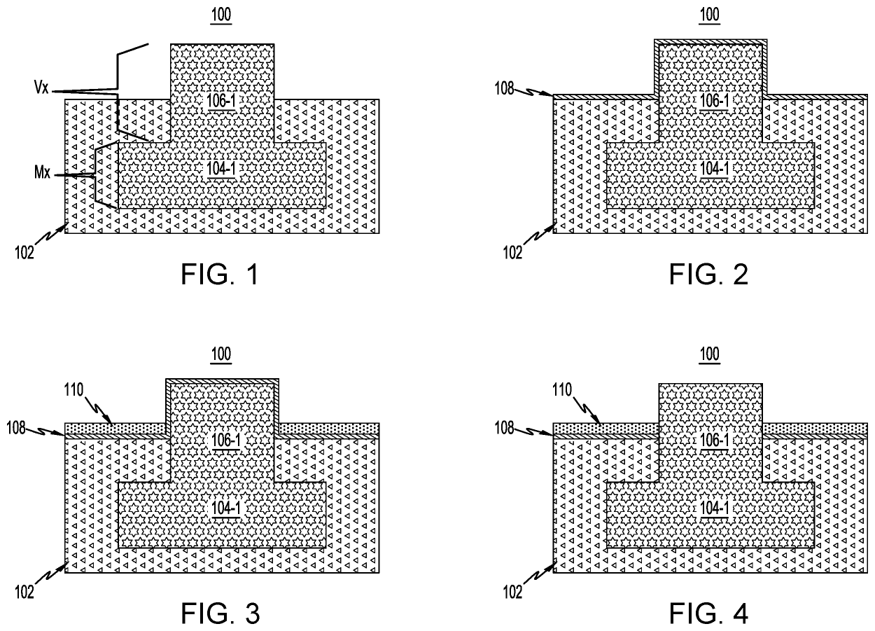

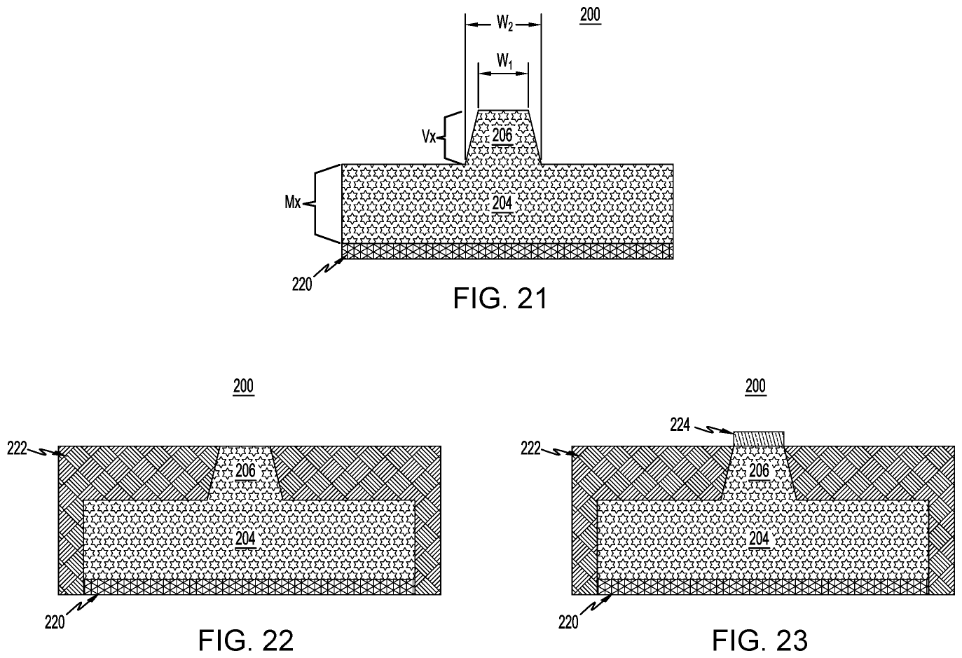

Accordingly, referring now to the drawings in which like numerals represent the same of similar elements, FIGS. 1-33 illustrate various processes for fabricating interconnects with via structures having no liner at the interface between a metal line of a metallization layer. Note that the same reference numeral (100) is used to denote the semiconductor structure through the various intermediate fabrication stages illustrated in FIGS. 1-20 and the same reference numeral (200) is used to denote the semiconductor structure through the various intermediate fabrication stages illustrated in FIGS. 21-33. Note also that the semiconductor structure described herein can also be considered to be a semiconductor device and/or an integrated circuit, or some part thereof. For the purpose of clarity, some fabrication steps leading up to the production of the semiconductor structures as illustrated in FIGS. 1-33 are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

Referring now to FIGS. 1-7, FIG. 1 shows a side cross-sectional view of a semiconductor structure 100, following formation of a first metallization layer Mx disposed in dielectric layer 102 and via layer Vx. Semiconductor structure 100 illustrates a first metallization layer Mx (where x is an integer greater than or equal to 1) having a metal line 104-1, disposed in dielectric layer 102. To form the first metallization layer Mx, a dielectric layer 102 is typically deposited on a substrate layer (not shown). Dielectric layer 102 may be made of any known dielectric material such as, for example, silicon oxide, silicon nitride, hydrogenated silicon carbon oxide, low-k dielectrics, ultralow-k dielectrics, flowable oxides, porous dielectrics, or organic dielectrics including porous organic dielectrics. Low-k dielectric materials have a nominal dielectric constant less than the dielectric constant of SiO₂, which is approximately 4 (e.g., the dielectric constant for thermally grown silicon dioxide can range from 3.9 to 4.0). In one embodiment, low-k dielectric materials may have a dielectric constant of less than 3.7. Suitable low-k dielectric materials include, for example, fluorinated silicon glass (FSG), carbon doped oxide, a polymer, a SiCOH-containing low-k material, a non-porous low-k material, a porous low-k material, a spin-on dielectric (SOD) low-k material, or any other suitable low-k dielectric material. Ultra-low-k dielectric materials have a nominal dielectric constant less than 2.5. Suitable ultra-low-k dielectric materials include, for example, SiOCH, porous pSiCOH, pSICNO, carbon rich silicon carbon nitride (C-Rich SiCN), porous silicon carbon nitride (pSiCN), boron and phosporous doped SiCOH/pSiCOH and the like.

The dielectric layer 102 may be formed by any suitable deposition technique known in the art, including atomic layer deposition (ALD), chemical vapor deposition (CVD), plasma enhanced chemical vapor deposition (PECVD), physical vapor deposition (PVD), molecular beam deposition (MBD), pulsed laser deposition (PLD), chemical solution deposition or other like processes. Subsequently, a planarization process such as a standard planarization process (e.g., a chemical mechanical planarization (CMP) process) can be carried out to planarize the upper surface of dielectric layer 102.

The substrate layer (not shown) can include a semiconductor material, which can be selected from, but is not limited to, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. Typically, the semiconductor material includes silicon. The substrate layer can include a bulk semiconductor substrate or a semiconductor-on-insulator (SOI) substrate. Also, the substrate layer can be at least one semiconductor device such as a field effect transistor, a bipolar transistor, a diode, a resistor, a capacitor, an inductor, an electrically programmable fuse, or any combination thereof.

Although the first metallization layer Mx of semiconductor structure 100 shows one metal line 104-1, first metallization layer Mx can contain a plurality of metal lines as discussed below which are formed using photolithography, etching and deposition processes. For example, in illustrative embodiments, a pattern (not shown) is produced on dielectric layer 102 by applying a photoresist to the surface to be etched; exposing the photoresist to a pattern of radiation; and then developing the pattern into the photoresist utilizing resist developer. Once the patterning of the photoresist is completed, the photoresist is removed. The etching process may be a subtractive etch, e.g., an anisotropic etch, such as reactive ion etch (RIE). The etch process may also be a selective etch process.

A conductive metal can then be deposited in the openings formed in patterned dielectric layer 102 using any conventional deposition process such as ALD, PVD, CVD or electroplating to form the metal lines in the first metallization layer Mx. A suitable conductive metal includes, for example, aluminum (Al), chromium (Cr), cobalt (Co), hafnium (Hf), iridium (Ir), molybdenum (Mo), niobium (Nb), osmium (Os), rhenium (Re), rhodium (Rh), ruthenium (Ru), tantalum (Ta), titanium (Ti), tungsten (W), vanadium (V), zirconium (Zr), and alloys thereof. In one embodiment, a conductive metal is Ru. Subsequently, a planarization process such as a standard planarization process (e.g., a CMP process) can be carried out to planarize the upper surface of the semiconductor structure 100.

Next, via layer Vx containing metal via 106-1 is formed on metal line 104-1 of the first metallization layer Mx to connect the first metallization layer Mx with a second metallization layer (Mx+1) as discussed below. Although the via layer Vx of semiconductor structure 100 shows one metal via 106-1, via layer Vx can contain a plurality of metal vias formed on respective metal lines of first metallization layer Mx as discussed below. Metal via 106-1 can be formed by depositing a conductive metal layer on the first metallization layer Mx and in dielectric layer 102 using any conventional deposition process such as ALD, PVD, CVD or electroplating and subsequent etching process such as RIE. A suitable conductive metal can be any of the conductive metals discussed above. The dielectric layer 102 is recessed to below a top surface of the metal via 106-1 using a conventional etching process such as RIE.

FIG. 2 illustrates semiconductor structure 100 at a second-intermediate stage. During this stage, a liner layer 108 is formed on the exterior surfaces of dielectric layer 102 and metal via 106-1 by any suitable deposition technique known in the art, including ALD, PVD and CVD. Liner layer 108 can be formed of a conductive liner material. A suitable conductive liner material includes any suitable conductive material in accordance with the embodiments described herein. In one embodiment, suitable liner materials for liner layer 108 include, for example, cobalt (Co), molybdenum (Mo), ruthenium (Ru), etc. In one embodiment, suitable liner materials for liner layer 108 include, for example, tantalum nitride (TaN), titanium nitride (TiN), titanium oxide (TiOx) and/or tungsten carbide (WC). In illustrative embodiments, liner layer 108 is a single layer. In illustrative embodiments, liner layer 108 includes a plurality of layers. In illustrative embodiments, liner layer 108 includes a plurality of layers each of a different conductive liner material. Liner layer 108 can have a thickness ranging from about 0.5 nanometers (nm) to about 10 nm.

FIG. 3 illustrates semiconductor structure 100 at a third-intermediate stage. During this stage, spin-on layer 110 is selectively formed on liner layer 108 over dielectric layer 102 and exposing liner layer 108 over metal via 106-1. Spin-on layer 110 can be formed using any conventional deposition process such spin-on coating or any other suitable deposition process. Spin-on layer 110 can be formed of any suitable spin-on material such as, for example, organic spin-on glass. Spin-on layer 110 can have a thickness ranging from about 1 nm to about 10 nm.

FIG. 4 illustrates semiconductor structure 100 at a fourth-intermediate stage. During this stage, the exposed liner layer 108 is selectively removed from semiconductor structure 100 using any standard wet or dry etch. For example, in non-limiting illustrative embodiments, a wet etching process may comprise etching in diluted hydrofluoric acid (DHF); potassium hydroxide (KOH) solution; ammonia; a solution containing hydrofluoric acid (HF), nitric acid (HNO₃), and/or acetic acid (CH₃COOH); or other suitable wet etchants. For example, in non-limiting illustrative embodiments, a dry etching process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As used herein, the term “selective” in reference to a material removal process denotes that the rate of material removal for a first material is greater than the rate of removal for at least another material of the structure to which the material removal process is being applied.

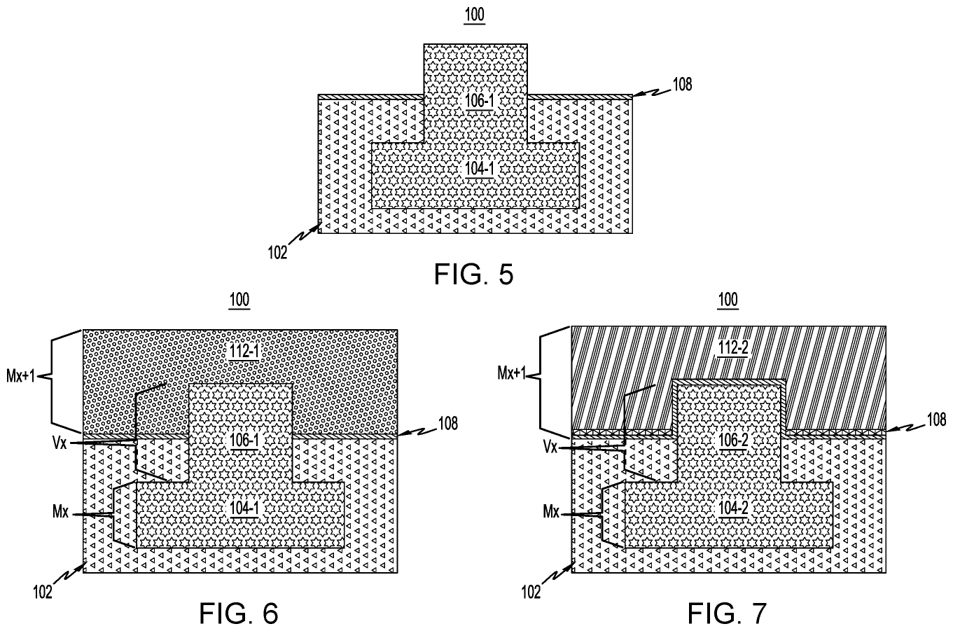

FIG. 5 illustrates semiconductor structure 100 at a fifth-intermediate stage. During this stage, spin-on layer 110 is selectively removed using any standard wet or dry etch to expose liner layer 108 and metal via 106-1.

FIG. 6 illustrates semiconductor structure 100 at a sixth-intermediate stage. During this stage, second metallization layer Mx+1 containing metal line 112-1 is formed on the metal via 106-1 and liner layer 108. Although the second metallization layer Mx+1 of semiconductor structure 100 shows one metal line 112-1, second metallization layer Mx+1 can contain a plurality of metal lines which can be formed by in a similar manner and of a similar material as discussed above for first metallization layer Mx.

The second metallization layer Mx+1 can further include a dielectric layer (not shown). The dielectric layer can include any suitable dielectric material in accordance with the embodiments described herein. For example, the dielectric layer can be formed by a similar process and of a similar material as dielectric layer 102.

Although the semiconductor structure 100 of FIGS. 1-6 show first metallization layer Mx containing one metal line, via layer Vx containing one metal via and second metallization layer Mx+1 containing one metal line, each of these layers can further include additional metal lines for respective first metallization layer Mx and second metallization layer Mx+1 and additional metal vias for via layer Vx in accordance with the resulting semiconductor structure 100 of FIG. 6. In addition, semiconductor structure 100 of FIG. 6 can further include the illustrative embodiment of FIG. 7 in which first metallization layer Mx contains a second metal line 104-2 formed in dielectric layer 102 and via layer Vx contains second metal via 106-2 on second metal line 104-2. Liner layer 108 is formed on second metal line 104-2 and second metal via 106-2. Second metallization layer Mx+1 of semiconductor structure 100 shows a second metal line 112-2 formed on liner layer 108.

In a non-limiting illustrative embodiment, the conductive metal for forming first metallization layer Mx, via layer Vx and second metallization layer Mx+1 can be the same or different. In a non-limiting illustrative embodiment, the conductive metal for forming first and second metal lines 104-1 and 104-2 of first metallization layer Mx and first and second metal vias 106-1 and 106-2 of via layer Vx is different than the conductive metal for forming first and second metal lines 112-1 and 112-2 of second metallization layer Mx+1. In a non-limiting illustrative embodiment, the conductive metal for forming first and second metal lines 104-1 and 104-2 of first metallization layer Mx and first and second metal vias 106-1 and 106-2 of via layer Vx is the same as the conductive metal for forming first and second metal lines 112-1 and 112-2 of second metallization layer Mx+1.

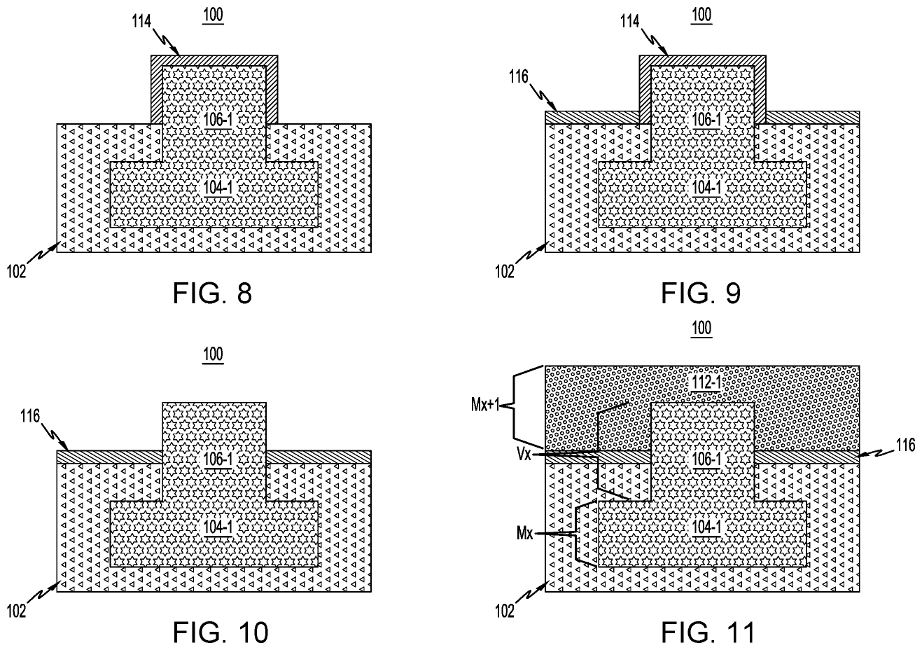

Referring now to FIGS. 8-11 illustrating an alternative non-limiting illustrative embodiment starting from FIG. 1, FIG. 8 illustrates semiconductor structure 100 at a first-intermediate fabrication stage. During this stage, self-assembled monolayer (SAM) 114 is formed on the exposed surface of metal via 106-1. The SAM 114 can be applied over the selected surfaces of metal via 106-1 by, for example, wet processing dipping in solution, spin-on and rinse as in standard lithography, or by vapor deposition or CVD under proper conditions. SAM 114 can have a thickness ranging from about 0.5 nm to about 5 nm.

As utilized herein, “self-assembled monolayer” (“SAM”) generally refers to a layer of molecules that are attached (e.g., by a chemical bond) to a surface and that have adopted a preferred orientation with respect to that surface and even with respect to each other. The SAM usually includes an organized layer of amphiphilic molecules in which one end of the molecule, the “head group” shows a specific, reversible affinity for a substrate. Selection of the head group will depend on the application of the SAM, with the type of SAM compounds based on the substrate utilized. Generally, the head group is connected to an alkyl chain or fluorinated alkyl chain in which a tail or “terminal end” can be functionalized, for example, to vary wetting and interfacial properties. The molecules that form the SAM will selectively attach to one material over another material (e.g., metal vs. dielectric) and if of sufficient density, can successfully operate subsequent deposition allowing for selective deposition on materials not coated with the SAM, etc.

Examples of suitable SAM molecules for SAM 114 which can be utilized in accordance with the implementations described herein include the materials described hereinafter, including combinations, mixtures, and grafts thereof, in addition to other SAM molecules having characteristics suitable for blocking deposition of subsequently deposited materials in a semiconductor fabrication process. In an illustrative embodiment, the SAM 114 can be formed from carboxylic acid materials, such as methylcarboxylic acids, ethycarboxylic acids, propylcarboxylic acids, butylcarboxylic acids, pentylcarboxylic acids, hexylcarboxylic acids, heptylcarboxylic acids, octylcarboxylic acids, nonylcarboxylic acids, decylcarboxylic acids, undecylcarboxylic acids, dodecylcarboxylic acids, tridecylcarboxylic acids, tetradecylcarboxylic acids, pentadecylcarboxylic acids, hexadecylcarboxylic acids, heptadecylcarboxylic acids, octadecylcarboxylic acids, and nonadecylcarboxylic acids.

In another illustrative embodiment, the SAM 114 can be formed from hydroxamic acid materials, such as suberoyl anilide hydroxamic acids, cinnamyl hydroxamic acid, sulfonamide hydroxamic acids, succinimide hydroxamic acids, pyrimidine-derived hydroxamic acids, heterocyclic-amide hydroxamic acids, and cyclic hydroxamic acids.

In another illustrative embodiment, the SAM 114 can be formed from phosphonic acid materials, such as methylphosphonic acid, ethylphosphonic acid, propylphosphonic acid, butylphosphonic acid, pentylphosphonic acid, hexylphosphonic acid, heptylphosphonic acid, octylphosphonic acid, nonylphosphonic acid, decylphosphonic acid, undecylphosphonic acid, dodecylphosphonic acid, tridecylphosphonic acid, tetradecyphosphonic acid, pentadecylphosphonic acid, hexadecylphosphonic acid, heptadecylphosphonic acid, octadecylphosphonic acid, and nonadecylphosphonic acid.

In another illustrative embodiment, the SAM 114 can be formed from thiol materials, such as methanethiol, ethanethiol, propanethiol, butanethiol, pentanethiol, hexanethiol, heptanethiol, octanethiol, nonanethiol, decanethiol, undecanethiol, dodecanethiol, tridecanethiol, tetradecanethiol, pentadecanethiol, hexadecanethiol, heptadecanethiol, octadecanethiol, and nonadecanethiol.

In another illustrative embodiment, the SAM 114 can be formed from silylamine materials, such as tris(dimethylamino)methylsilane, tris(dimethylamino)ethylsilane, tris(dimethylamino)butylsilane, tris(dimethylamino)hexylsilane, tris(dimethylamino)propylsilane, tris(dimethylamino)pentylsilane, tris(dimethylamino)heptylsilane, tris(dimethylamino)octylsilane, tris(dimethylamino)nonylsilane, tris(dimethylamino)decylsilane, tris(dimethylamino)undecylsilane tris(dimethylamino)tridecylsilane, tris(dimethylamino)pentadecylsilane, tris(dimethylamino)heptadecylsilane, tris(dimethylamino)dodecylsilane, tris(dimethylamino)tetradecylsilane, tris(dimethylamino)hexadecylsilane, tris(dimethylamino)octadecylsilane, and tris(dimethylamino)nonadecylsilane.

In another illustrative embodiment, the SAM 114 can be formed from chlorosilane materials, such as methyltrichlorosilane, ethyltrichlorosilane, propyltrichlorosilane, butyltrichlorosilane, pentyltrichlorosilane, hexyltrichlorosilane, heptyltrichlorosilane, octyltrichlorosilane, nonyltrichlorosilane, decyltrichlorosilane, undecyltrichlorosilane, tetradecyltrichlorosilane, dodecyltrichlorosilane, tridecyltrichlorosilane, heptadecyltrichlorosilane, pentadecyltrichlorosilane, hexadecyltrichlorosilane, octadecyltrichlorosilane, and nonadecyltrichlorosilane.

In another illustrative embodiment, the SAM 114 can be formed from oxysilane materials, such as methyltrimethoxysilane, methyltriethoxysilane, ethyltrimethoxysilane, ethyltriethoxysilane, propyltrimethoxysilane, propyltriethoxysilane, butyltrimethoxysilane, butyltriethoxysilane, pentyltrimethoxysilane, pentyltriethoxysilane, hexyltrimethoxysilane, hexyltriethoxysilane, heptyltrimethoxysilane, heptyltriethoxysilane, octyltrimethoxysilane, nonyltriethoxysilane, decyltrimethoxysilane, octyltriethoxysilane, nonyltrimethoxysilane, decyltriethoxysilane, undecyltrimethoxysilane, undecyltrethoxysilane, dodecyltrimethoxysilane, dodecyltriethoxysilane, tridecyltrimethoxysilane, tridecyltriethoxysilane, tetradecyltrimethoxysilane, tetradecyltriethoxysilane, pentadecyltrimethoxysilane, pentadecyltriethoxysilane, hexadecyltrimethoxysilane, hexadecyltroethoxysilane, heptadecyltrimethoxysilane, heptadecyltriethoxysilane, octadecyltrimethoxylsilane octadecyltriethoxysilane, nonadecyltrimethoxysilane, and nonadecyltriethoxysilane.

In another illustrative embodiment, the SAM 114 can formed from a material having a fluorinated R group, such as (1,1,2,2-perfluorodecyl)trichlorosilane, trichloro(1,1,2,2-perflrorooctyl)silane, (trideca-fluoro-1,1,2,2-tetrahydrooctyl)trichlorosilane, (tridecafluoro-1,1,2,2-tetrahydro-octyl)triethoxysilane, (tridecafluoro-1,1,2,2-tetrahydrooctyl)methyldichlorosilane, (tridecafluoro-1,1,2,2-tetrahydrooctyl)dimethylchlorosilane, and (heptadecafluoro-1,1,2,2-tetrahydrodecyl)trichlorosilane, among others.

FIG. 9 illustrates semiconductor structure 100 at a second-intermediate stage. During this stage, a liner layer 116 is formed on the exterior surfaces of dielectric layer 102 and on a portion of a sidewall of SAM 114. Liner layer 116 can be formed by similar processes and of similar material as liner layer 108. Liner layer 116 can have a thickness ranging from about 0.5 nm to about 10 nm.

FIG. 10 illustrates semiconductor structure 100 at a third-intermediate stage. During this stage, SAM 114 is selectively removed using any standard wet or dry etch to expose a portion of dielectric layer 102. Next, liner layer 116 is formed on the exposed portion of dielectric layer 102.

FIG. 11 illustrates semiconductor structure 100 at a fourth-intermediate stage. During this stage, second metallization layer Mx+1 containing metal line 112-1 is formed on the metal via 106-1 and liner layer 108. Second metallization layer Mx+1 is formed by depositing a conductive metal on metal via 106-1 and liner layer 108 in a similar manner and of a similar material as discussed above.

The second metallization layer Mx+1 can further include a dielectric layer (not shown). The dielectric layer can include any suitable dielectric material in accordance with the embodiments described herein. For example, the dielectric layer can be formed by a similar process and of a similar material as dielectric layer 102.

In a non-limiting illustrative embodiment, the conductive metal for forming first metallization layer Mx, via layer Vx and second metallization layer Mx+1 can be the same or different. In a non-limiting illustrative embodiment, the conductive metal for forming via layer Vx is different than the conductive metal for forming second metallization layer Mx+1. In a non-limiting illustrative embodiment, the conductive metal for forming via layer Vx is the same as the conductive metal for forming second metallization layer Mx+1 can be the same or different.

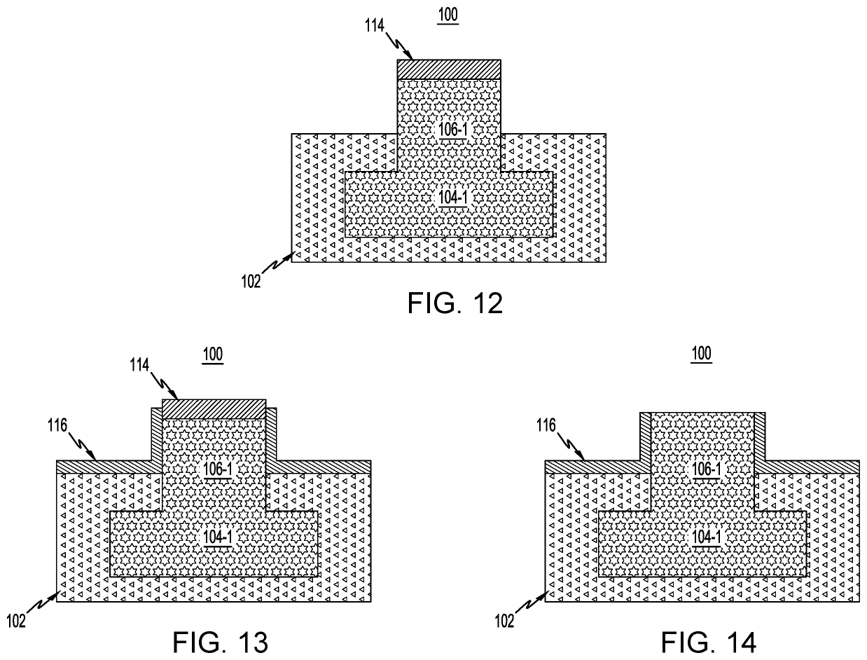

Referring now to FIGS. 12-15 illustrating another alternative non-limiting illustrative embodiment starting from FIG. 1, FIG. 12 illustrates semiconductor structure 100 at a first-intermediate fabrication stage. During this stage, SAM 114 is formed on the top surface of metal via 106-1. SAM 114 can be formed using similar methods and of similar material as discussed above. SAM 114 can have a thickness ranging from about 0.5 nm to about 5 nm.

FIG. 13 illustrates semiconductor structure 100 at a second-intermediate stage. During this stage, a liner layer 116 is formed on the exterior surfaces of dielectric layer 102, metal via 106-1 and on a portion of a sidewall of SAM 114. Liner layer 116 can be formed by similar processes and of similar material as liner layer 108. Liner layer 116 can have a thickness ranging from about 0.5 nm to about 10 nm.

FIG. 14 illustrates semiconductor structure 100 at a third-intermediate stage. During this stage, SAM 114 is selectively removed using any standard wet or dry etch to expose a portion of metal via 106-1. Next, liner layer 116 is recessed so that the top surface of liner layer 116 is aligned with the top surface of metal via 106-1 using, for example, RIE.

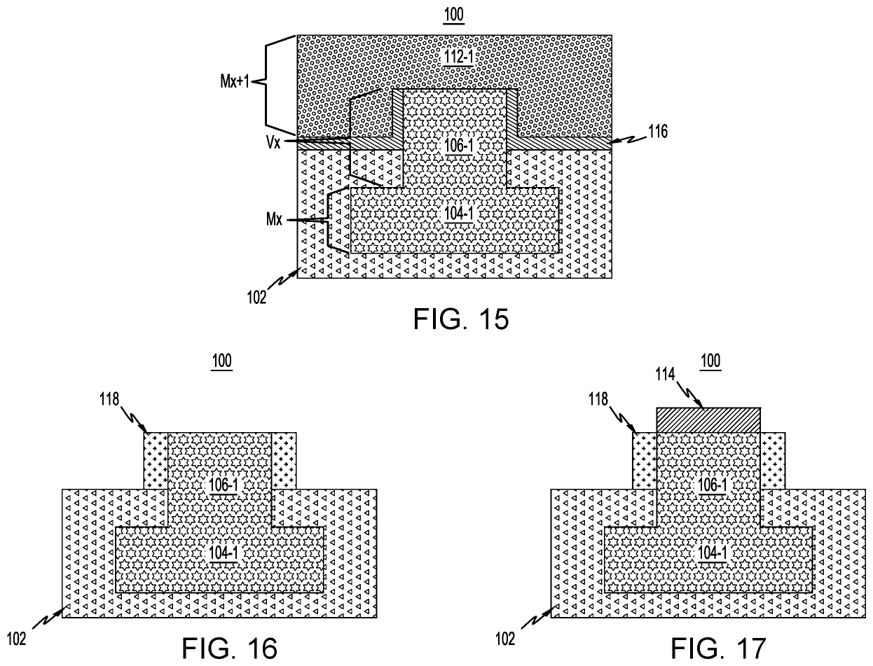

FIG. 15 illustrates semiconductor structure 100 at a fourth-intermediate stage. During this stage, second metallization layer Mx+1 containing metal line 112-1 is formed on the metal via 106 and liner layer 108. Second metallization layer Mx+1 containing metal line 112-1 is formed by depositing a conductive metal on metal via 106-1 and liner layer 108 in a similar manner and of a similar material as discussed above.

The second metallization layer Mx+1 can further include a dielectric layer (not shown). The dielectric layer can include any suitable dielectric material in accordance with the embodiments described herein. For example, the dielectric layer can be formed by a similar process and of a similar material as dielectric layer 102.

In a non-limiting illustrative embodiment, the conductive metal for forming first metallization layer Mx, via layer Vx and second metallization layer Mx+1 can be the same or different. In a non-limiting illustrative embodiment, the conductive metal for forming via layer Vx is different than the conductive metal for forming second metallization layer Mx+1. In a non-limiting illustrative embodiment, the conductive metal for forming via layer Vx is the same as the conductive metal for forming second metallization layer Mx+1 can be the same or different.

Referring now to FIGS. 16-20 illustrating another alternative non-limiting illustrative embodiment starting from FIG. 1, FIG. 16 illustrates semiconductor structure 100 at a first-intermediate fabrication stage. During this stage, sidewall spacers 118 are formed on the exposed sidewalls of metal via 106-1 using conventional deposition techniques such as by ALD, CVD and PVD. In one illustrative embodiment, sidewall spacers 118 can be a nitride or an oxynitride such as, for example, Si₃N₄, SiBCN, SiNC, SiN, SiCO, SiO₂ and SiNOC. Sidewall spacers 118 can have a thickness ranging from about 0.5 nm to about 5 nm.

FIG. 17 illustrates semiconductor structure 100 at a second-intermediate stage. During this stage, SAM 114 is selectively formed on the top surface of metal via 106-1. SAM 114 can be formed using similar methods and of similar material as discussed above. SAM 114 can have a thickness ranging from about 0.5 nm to about 5 nm.

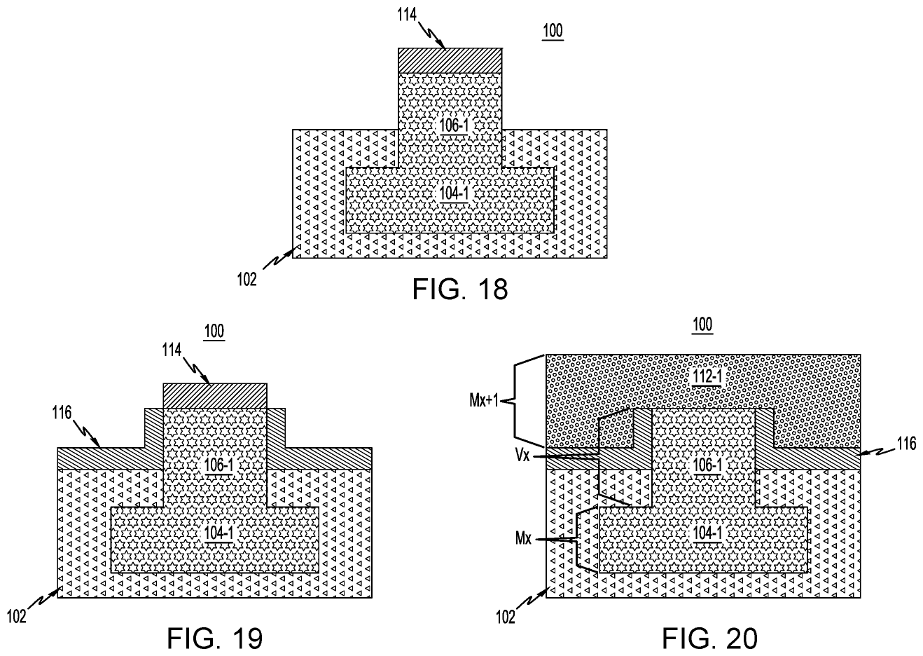

FIG. 18 illustrates semiconductor structure 100 at a third-intermediate stage. During this stage, sidewall spacers 118 are removed using any wet or dry etch.

FIG. 19 illustrates semiconductor structure 100 at a fourth-intermediate stage. During this stage, a liner layer 116 is formed on the exterior surfaces of dielectric layer 102, metal via 106-1 and on a portion of a sidewall of SAM 114. Liner layer 116 can be formed by similar processes and of similar material as liner layer 108. Liner layer 116 can have a thickness ranging from about 0.5 nm to about 10 nm.

FIG. 20 illustrates semiconductor structure 100 at a fifth-intermediate stage. During this stage, SAM 114 is selectively removed using any standard wet or dry etch to expose a portion of metal via 106. Liner layer 116 is recessed so that the top surface of liner layer 116 is aligned with the top surface of metal via 106-1 using, for example, RIE.

Next, second metallization layer Mx+1 containing metal line 112-1 is formed on the metal via 106-1 and liner layer 116. Second metallization layer Mx+1 containing metal line 112-1 is formed by depositing a conductive metal on metal via 106-1 and liner layer 108 in a similar manner and of a similar material as discussed above.

The second metallization layer Mx+1 can further include a dielectric layer (not shown). The dielectric layer can include any suitable dielectric material in accordance with the embodiments described herein. For example, the dielectric layer can be formed by a similar process and of a similar material as dielectric layer 102.

In a non-limiting illustrative embodiment, the conductive metal for forming first metallization layer Mx, via layer Vx and second metallization layer Mx+1 can be the same or different. In a non-limiting illustrative embodiment, the conductive metal for forming via layer Vx is different than the conductive metal for forming second metallization layer Mx+1. In a non-limiting illustrative embodiment, the conductive metal for forming via layer Vx is the same as the conductive metal for forming second metallization layer Mx+1 can be the same or different.

Referring now to FIGS. 21-26 illustrating another alternative non-limiting illustrative embodiment, FIG. 21 illustrates semiconductor structure 200 at a first-intermediate fabrication stage, following formation of liner layer 220, first metallization layer Mx containing metal line 204 and via layer Vx containing metal via 206. Liner layer 220 is typically deposited on a substrate layer (not shown) as discussed above using similar processes and of similar material as liner layer 108. Liner layer 220 can have a thickness ranging from about 0.5 nm to about 5 nm.

The first metallization layer Mx containing metal line 204 may be formed in a similar manner as discussed above for first metallization layer Mx containing metal line 104-1. Next, via layer Vx containing metal via 206 is formed on the metal line 204 of first metallization layer Mx to connect the first metallization layer Mx with a second metallization layer (Mx+1) as discussed below. Metal via 206 can be formed using photolithography, etching and deposition processes. For example, in some embodiments, a pattern (not shown) is produced on a dielectric layer (not shown) by applying a photoresist to the surface to be etched, exposing the photoresist to a pattern of radiation, and then developing the pattern into the photoresist utilizing resist developer. Once the patterning of the photoresist is completed, the photoresist is removed. The etching process may be a subtractive etch, e.g., an anisotropic etch, such as RIE. The etch process may also be a selective etch process.

A conductive metal can then be deposited in the opening formed in the patterned dielectric layer using any conventional deposition process such as ALD, PVD, CVD or electroplating. can be any of those discussed above. Subsequently, a planarization process such as a standard planarization process (e.g., a CMP process) can be carried out to planarize the upper surface of metal via 206 and the dielectric layer can be removed. In forming the metal via 206 according to the illustrative embodiment, a top portion of metal via 206 will have a width W₁ and a bottom portion of metal via 206 will have a width W₂ that is a width greater than width W₁. In an embodiment, the width W₁ can range from about 5 nm to about 50 nm and the width W₂ can range from about 6 nm to about 60 nm.

FIG. 22 illustrates semiconductor structure 200 at a second-intermediate stage. During this stage, a dielectric layer 222 may be formed over semiconductor structure 200 by any suitable deposition technique known in the art, including ALD, CVD, PECVD, PVD, MBD, PLD, chemical solution deposition or other like processes. Subsequently, a planarization process such as a standard planarization process (e.g., a CMP process) can be carried out to planarize the upper surface of dielectric layer 122 and expose the top surface of metal via 206.

FIG. 23 illustrates semiconductor structure 200 at a third-intermediate stage. During this stage, SAM 224 is selectively formed on the top surface of metal via 206. SAM 224 can be formed using similar methods and of similar material as discussed above for SAM 114. SAM 224 can have a thickness ranging from about 0.5 nm to about 5 nm.

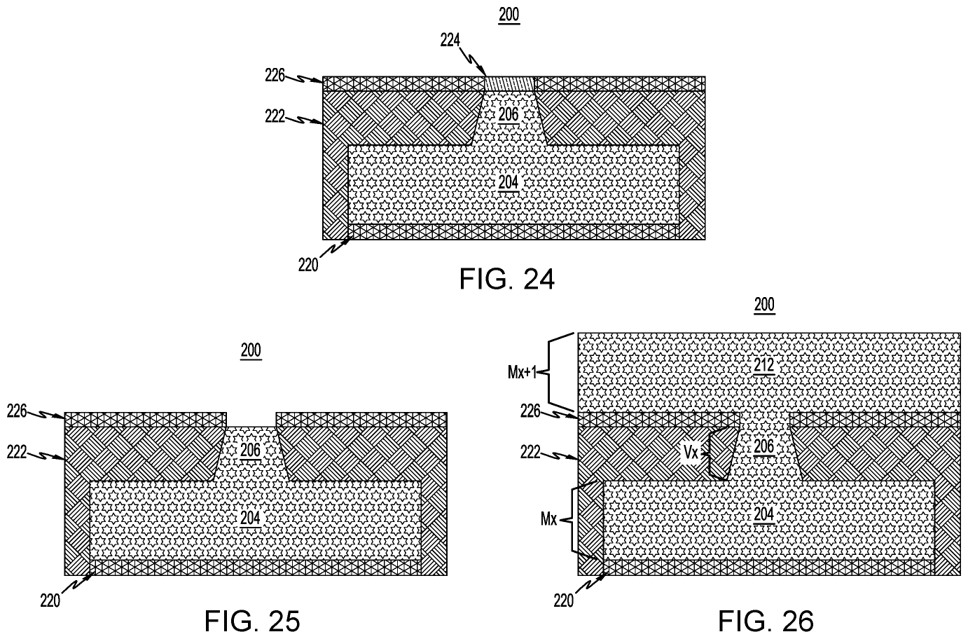

FIG. 24 illustrates semiconductor structure 200 at a fourth-intermediate stage. During this stage, a liner layer 226 is formed on the exterior surfaces of dielectric layer 222 and on a sidewall of SAM 224. Liner layer 226 can be formed by similar processes and of similar material as liner layer 108. Liner layer 226 can have a thickness ranging from about 0.5 nm to about 10 nm.

FIG. 25 illustrates semiconductor structure 200 at a fifth-intermediate stage. During this stage, SAM 224 is selectively removed using any standard wet or dry etch to expose the top surface of metal via 206.

FIG. 26 illustrates semiconductor structure 200 at a sixth-intermediate stage. During this stage, second metallization layer Mx+1 containing metal line 212 is formed on the metal via 206 and liner layer 226. Second metallization layer Mx+1 containing metal line 212 is formed by depositing a conductive metal on metal via 206 and liner layer 226 in a similar manner and of a similar material as discussed above for second metallization layer Mx+1 containing metal line 112-1.

The second metallization layer Mx+1 can further include a dielectric layer (not shown). The dielectric layer can include any suitable dielectric material in accordance with the embodiments described herein. For example, the dielectric layer can be formed by a similar process and of a similar material as dielectric layer 102.

In a non-limiting illustrative embodiment, the conductive metal for forming first metallization layer Mx, via layer Vx and second metallization layer Mx+1 can be the same or different. In a non-limiting illustrative embodiment, the conductive metal for forming via layer Vx is different than the conductive metal for forming second metallization layer Mx+1. In a non-limiting illustrative embodiment, the conductive metal for forming via layer Vx is the same as the conductive metal for forming second metallization layer Mx+1 can be the same or different.

Although the semiconductor structure 200 of FIGS. 21-26 shows first metallization layer Mx containing one metal line, via layer Vx containing one metal via and second metallization layer Mx+1 containing one metal line, each of these layers can further include additional metal lines for respective first metallization layer Mx and second metallization layer Mx+1 and additional metal vias for via layer Vx in accordance with the resulting semiconductor structure 200 of FIG. 26. In addition, semiconductor structure 200 of FIG. 26 can further include the illustrative embodiment of FIG. 7 in which first metallization layer Mx contains a second metal line 104-2 formed in dielectric layer 102 and via layer Vx contains second metal via 106-2 on second metal line 104-2. A liner layer 108 is formed on second metal line 104-2 and second metal via 106-2. Second metallization layer Mx+1 can include a second metal line 112-2 formed on liner layer 108.

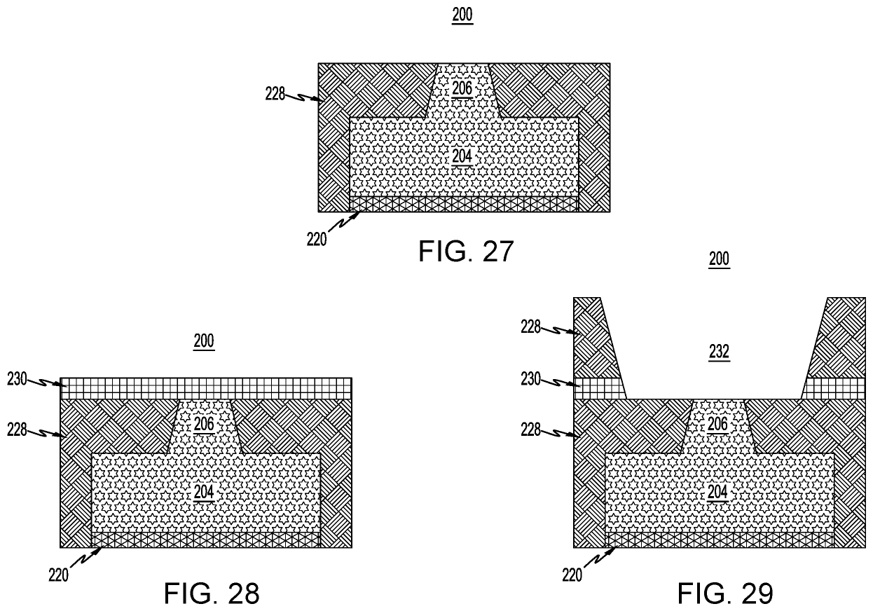

Referring now to FIGS. 27-33 illustrating another alternative non-limiting illustrative embodiment starting from FIG. 21, FIG. 27 illustrates semiconductor structure 200 at a first-intermediate fabrication stage, following formation of dielectric layer 228 over semiconductor structure 200 by any suitable deposition technique and material as discussed above for dielectric layer 222.

FIG. 28 illustrates semiconductor structure 100 at a second-intermediate stage. During this stage, liner layer 230 is formed on the top surface of dielectric layer 228 and metal via 206. Liner layer 230 can be formed using similar methods and of similar material as discussed above for liner layer 108. Liner layer 230 can have a thickness ranging from about 0.5 nm to about 10 nm.

FIG. 29 illustrates semiconductor structure 200 at a third-intermediate stage. During this stage, an additional dielectric layer 228 is formed on the liner layer 230 and subjected to photolithography and etching processes to form the dual damascene type structure 232. The etching process removes the liner layer 230 in the dual damascene type structure 232 and exposes dielectric layer 228 and metal via 206.

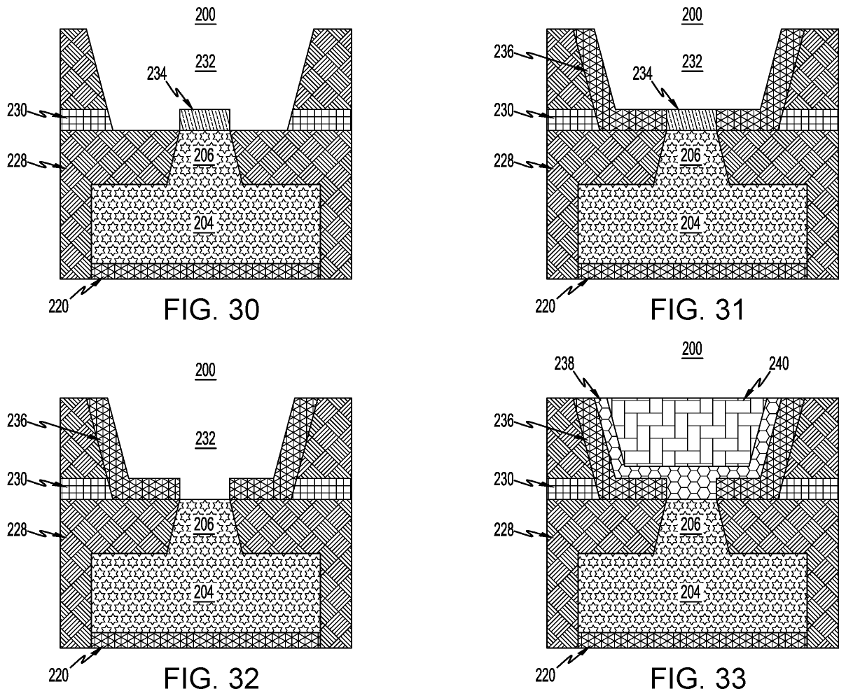

FIG. 30 illustrates semiconductor structure 200 at a fourth-intermediate stage. During this stage, SAM 234 is selectively formed on the top surface of metal via 206. SAM 234 can be formed using similar methods and of similar material as discussed above for SAM 214. SAM 234 can have a thickness ranging from about 0.5 nm to about 5 nm.

FIG. 31 illustrates semiconductor structure 200 at a fifth-intermediate stage. During this stage, a barrier layer 236 is formed on the exterior surfaces of dielectric layer 228 and on a sidewall of SAM 234. Barrier layer 236 is formed by depositing a conformal barrier layer into and lining the dual damascene type structure 232. Suitable barrier layer materials include, for example, tantalum nitride (TaN), titanium nitride (TiN), titanium oxide (TiOx) and/or tungsten carbide (WC). A conformal deposition process such as ALD or PVD can be employed to deposit the barrier layer into and lining the dual damascene type structure 232. For instance, according to an exemplary embodiment, a thermal ALD process at a temperature of from about 250° C. to about 300° C. and ranges therebetween is employed to deposit the barrier layer into the dual damascene type structure 232. In one exemplary embodiment, the barrier layer has a thickness of from about 2 nm to about 5 nm.

FIG. 32 illustrates semiconductor structure 200 at a sixth-intermediate stage. During this stage, SAM 234 is selectively removed in dual damascene type structure 232 using any standard wet or dry etch to expose the top surface of metal via 206.

FIG. 33 illustrates semiconductor structure 200 at a sixth-intermediate stage. During this stage, liner layer 238 is deposited on the bottom surfaces and sidewalls of dual damascene type structure 232 using a conventional deposition process, for example, CVD, PECVD, PVD, plating, thermal or e-beam evaporation, sputtering, etc. In one embodiment, liner layer 238 is a metal liner. Suitable material for liner layer 238 includes, for example, TiN, TaN, etc. In general, liner layer 238 can have a thickness ranging from about 0.5 nm to about 10 nm.

Next, a conductive metal is deposited on liner layer 238 and filling dual damascene type structure 232 to form second metallization layer Mx+1 containing metal line 140. Second metallization layer Mx+1 is formed in a similar manner and of a similar material as discussed above.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An interconnect structure, comprising:
a first metal via disposed on a first metal line of a first metallization layer disposed in a dielectric layer;
a first liner layer disposed on the dielectric layer; and
a second metallization layer comprising a first metal line disposed on the first liner layer and the first metal via.

2. The interconnect structure according to claim 1, wherein the first metal via comprises a first portion extending from the first metal line of the first metallization layer to a top surface of the dielectric layer and a second portion extending above the top surface of the dielectric layer and within the first metal line of the second metallization layer.

3. The interconnect structure according to claim 1, wherein the first metal via comprises a first conductive metal and the first metal line of the second metallization layer comprises a second conductive metal.

4. The interconnect structure according to claim 3, wherein the first conductive metal is the same as the second conductive metal.

5. The interconnect structure according to claim 3, wherein the first conductive metal is different than the second conductive metal.

6. The interconnect structure according to claim 1, wherein the first liner layer comprises a single layer.

7. The interconnect structure according to claim 1, wherein the first liner layer comprises a plurality of layers.

8. The interconnect structure according to claim 1, wherein the first liner layer comprises a plurality of layers each of a different conductive liner material.

9. The interconnect structure according to claim 1, wherein the first liner layer is disposed on sidewalls of the first metal via.

10. The interconnect structure according to claim 1, further comprising:
a second metal via disposed on a second metal line of the first metallization layer;
a second liner layer disposed on the dielectric layer and the second metal via; and
a second metal line of the second metallization layer disposed on the second liner layer.

11. An interconnect structure, comprising:
a first metal via disposed on a first metal line of a first metallization layer disposed in a dielectric layer;
a first liner layer disposed on the dielectric layer; and
a second metallization layer comprising a first metal line disposed on the first liner layer and the first metal via
wherein a top portion of the first metal via has a first width and a bottom portion of the first metal via has a second width different than the first width.

12. The interconnect structure according to claim 11, wherein the first width is less than the second width.

13. The interconnect structure according to claim 11, wherein the first metal via comprises a first portion extending from the first metal line of the first metallization layer to a top surface of the dielectric layer and a second portion extending above the top surface of the dielectric layer and within the first metal line of the second metallization layer.

14. The interconnect structure according to claim 11, wherein the first metal via comprises a first conductive metal and the first metal line of the second metallization layer comprises a second conductive metal different than the first conductive metal.

15. The interconnect structure according to claim 11, wherein the first liner layer comprises a single layer.

16. The interconnect structure according to claim 11, wherein the first liner layer comprises a plurality of layers.

17. The interconnect structure according to claim 11, wherein the first liner layer comprises a plurality of layers each of a different conductive liner material.

18. The interconnect structure according to claim 11, further comprising:
a second metal via disposed on a second metal line of the first metallization layer;
a second liner layer disposed on the dielectric layer and the second metal via; and
a second metal line of the second metallization layer disposed on the second liner layer.

19. An interconnect structure, comprising:
a first metallization layer comprising a metal line disposed in a first dielectric layer;
a metal via disposed on the metal line of a first metallization layer in the first dielectric layer;
a liner layer disposed on a portion of the first dielectric layer;
a second dielectric layer disposed on the liner layer and having a trench;
a barrier layer disposed on exterior surfaces of the first dielectric layer, the liner layer and the second dielectric layer;
a metal liner layer disposed on the barrier layer and the metal via; and
a conductive metal disposed on the metal liner layer.

20. The interconnect structure according to claim 19, wherein a top portion of the metal via has a first width and a bottom portion of the metal via has a second width different than the first width.
